(19) United States
(12) Patent Application Publication
(10) Pub. No.: US 2003/0204378 A1
(43) Pub. Date: Oct. 30, 2003

(54) System and method for forming a beam and creating nulls with an adaptive array antenna using orthogonal eigen-weighting

(76) Inventor: Khiem V. Cai, Brea, CA (US)

Correspondence Address: Leonard A. Alkov, Raytheon Company, P.O. Box 902 (E1/E150), El Segundo, CA, 90245-0902, US

(21) Appl. No.: 09/891,686

(22) Filed: Jun. 26, 2001

(51) Int. Cl. H03F 1/26; G06F 15/00; H04B 15/00

(52) U.S. Cl. 702/189

(57) ABSTRACT

An orthogonal weighting estimator for use in a beam forming system having an array of antenna elements and a receiver associated therewith. The inventive estimator computes eigenvalues associated with signals output by the receiver and identifies a target signal with respect to a characteristic thereof. In the illustrative embodiment, the characteristic is amplitude and the estimator further computes an eigenvector for at least the target signal. The estimator computes a covariance matrix from the receive signals and, after filtering, computes the eigenvalues and eigenvectors. The eigenvalues are then sorted and searched for matched signals. The estimator then uses the eigenvector of the target signal to compute the direction thereof. That is, by applying a weighting to the target signal, the signal to noise ratio of the received beam may be optimized in the direction of a target signal while simultaneously creating nulls and the direction of jamming signals.

### BACKGROUND OF THE INVENTION

1. Field of the Invention

The present invention relates to antennas. More specifically, the present invention relates to system and methods for forming beams and creating nulls using phased array antennas.

2. Description of the Related Art

Adaptive antenna systems have been developed to perform beam forming or spatial nulling. With knowledge of the direction of the signal source, conventional antenna beam forming techniques endeavor to maximize the signal to noise ratio with respect to signals sent to or received from desired sources and attempt to steer nulls and the direction of undesirable sources.

Unfortunately, in many cases it may be difficult to ascertain the direction of the signal source with sufficient accuracy. This is particularly problematic with respect to spread spectrum and other signals having a signal strength below the noise level.

Conventional beam forming techniques require knowledge of the direction of the signal sources and a method to track the angle of arrival of the signal on a moving platform. Two methods are generally employed to acquire knowledge of the direction of the signal source of interest: angle of arrival approaches and adaptive searching for the signal direction.

In the angle arrival approach, a receiver estimates the angle arrival of the desired signal and performs adaptive signal processing to maximize the gain of the beam in the pointing direction. With this approach, assumptions must be made with respect to the relative location of the signal source. However, for many applications, an assumption with respect to the location of the signal source may introduce an unacceptable amount of error into the process.

On a moving platform, an initial measurement unit (IMU) is required to maintain the desired pointing direction. This solution can be expensive and potentially require an IMU of considerable size and weight.

Further, in a dynamic environment, the signal sources may move around requiring a communication of a large amount of data from one platform to another. Hence, angle of arrival approaches tend to be expensive, cumbersome and prone to error.

In electronic warfare applications, adaptive searching is often used to identify the location of a source of a jamming signal. The searching is typically performed by sweeping a radar receiver in azimuth and/or elevation. Unfortunately, the efficacy of this approach is limited in situations where the jamming source is intermittently activated.

Hence, a need remains in the art for a more effective, less-expensive system or method for ascertaining the direction of a signal source relative to conventional approaches.

### SUMMARY OF THE INVENTION

The need the art is addressed by the present invention which provides an orthogonal weighting estimator for use in a beam forming system having an array of antenna elements and a receiver associated therewith. The inventive estimator computes eigenvalues associated with signals output by the receiver and identifies a target signal with respect to a characteristic thereof.

In the illustrative embodiment, the characteristic is amplitude and the estimator further computes an eigenvector for at least the target signal. The estimator computes a covariance matrix from the receive signals and, after filtering, computes the eigenvalues and eigenvectors. The eigenvalues are then sorted and searched for matched signals. The estimator then uses the eigenvector of the target signal to compute the direction thereof. That is, by applying a weighting to the target signal, the signal to noise ratio of the received beam may be optimized in the direction of a target signal while simultaneously creating nulls and the direction of jamming signals.

### BRIEF DESCRIPTION OF THE DRAWINGS

FIG. 1 is a block diagram of a beam forming system with an orthogonal eigen-weighting estimator implemented in accordance with the teachings of the present invention.

FIG. 2 is a graph showing and distribution of the eigenvalues of the received signals as may be generated by an illustrative implementation in accordance with the present teachings.

FIG. 3(a) is a schematic diagram showing the location of a 4 element antenna (+), jammers (*) and a DSPSN signal (o).

FIG. 3(b) is a diagram showing the spectrum before nulling which is a composite of three jammers and one signal.

FIG. 3(c) shows the spectrum of FIG. 3(b) resulting from a use of the eigenvector associated with eigenvalue λ₁ as the weighting.

FIG. 3(d) shows the spectrum of FIG. 3(b) resulting from a use of the eigenvector associated with eigenvalue λ₂ as the weighting.

FIG. 3(e) shows the spectrum of FIG. 3(b) resulting from a use of the eigenvector associated with eigenvalue λ₃ as the weighting.

FIG. 3(f) shows the spectrum of FIG. 3(b) resulting from a use of the eigenvector associated with eigenvalue λ₄ as weighting.

### DESCRIPTION OF THE INVENTION

Illustrative embodiments and exemplary applications will now be described with reference to the accompanying drawings to disclose the advantageous teachings of the present invention.

While the present invention is described herein with reference to illustrative embodiments for particular applications, it should be understood that the invention is not limited thereto. Those having ordinary skill in the art and access to the teachings provided herein will recognize additional modifications, applications, and embodiments within the scope thereof and additional fields in which the present invention would be of significant utility.

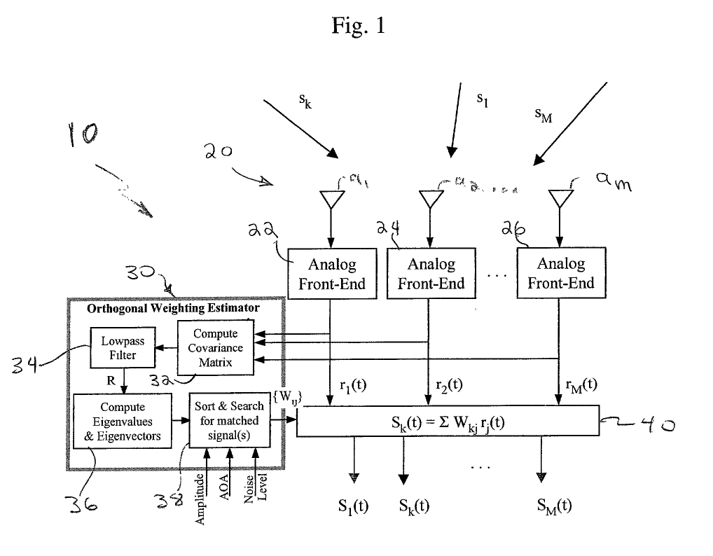

FIG. 1 is a block diagram of a beam forming system with an orthogonal eigen-weighting estimator implemented in accordance with the teachings of the present invention. As shown in FIG. 1, the beam forming system 10 includes an adaptive array 20 of M antenna elements a₁, a₂, . . . aₘ which receive multiple signals, e.g., S₁, Sₖ, and Sₘ. The output of each antenna elements a₁, a₂, . . . aₘ is processed by an associated analog front end receiver circuit 22, 24, . . . 26 respectively. The receiver circuits 22, 24, . . . 26 output received signals r₁(t), r₂(t) . . . rₘ(t), respectively. While some of the received signals may be of interest, others may be due to undesirable interference.

Hence, a key objective is to estimate the weighting that will steer a beam in the desired direction and at the same time form nulls in the direction of sources of interfering signals. In accordance with the present teachings, this is effected by an orthogonal weighting estimator 30. The estimator 30 may be implemented in hardware with field programmable gate arrays, programmable logic devices, or discrete logic or may be implemented in software with a microprocessor. For the purpose of illustration, a software implementation running on a microprocessor is presumed.

As discussed more fully below, the estimator 30 first computes an M×M covariance matrix from the received signals r₁(t), r₂(t) . . . rₘ(t) (using software running on a microprocessor shown generally at 32). Next, the estimator 30 averages the covariance matrix with a digital low pass filter (34) to improve the signal to noise ratio and computes the M eigenvalues and eigenvectors (36), where M is the number of antenna elements. Inasmuch as the eigenvalues correlate to the incoming signal amplitudes and the eigenvectors correlate to the direction of the incoming signal, these parameters, along with the noise level, target signal levels, angles of arrival, and the center frequency can be used to sort out which eigenvalue is associated with the desired signal (38). In accordance with the present teachings, it is this signal for which the estimator 30 then searches for the matching eigenvector as discussed more fully below.

Furthermore, the eigenvectors are orthogonal to each other, if an eigenvector associated with one signal is selected as the weighting of the antenna array then the resulting signal will form a beam on that signal, and at the same time form nulls in other signals (38). The eigenvector is then used as the weighting to the array antenna to form the beam to the desired signal and nulls to the stronger signal.

The output of the estimator 30 is fed to a combiner 40 which may be implemented as a Butler matrix or other corporate feed network. If the eigenvector (VI) corresponding to the largest eigenvalue is selected as the weighting then the output of the combiner 40 forms a beam at the strongest signal (S1). If the eigenvector (V2) corresponding to the second largest eigenvalue is selected as the weighting then the output of the combiner 40 forms a beam at the second strongest signal (S2), and as the same time form a null to strongest signal (S1). Following this sequence, if the eigenvector (Vk) corresponding to the kth largest eigenvalue is selected as the weighting then the output of the combiner 40 forms a beam at the kth strongest signal (Sk), and as the same time form nulls to all signals other than Sk.

V₁: =>S₁

V₂: | .V₁ & =>S₂

V₃: | .V₁ & | .V₂ & =>S₃

V_{M}: | .V₁ & | .V₂ & . . . & | .V_{M-1} & =>S_{M}

where Vₖ is the k^{th} eigenvector corresponding to signal Sₖ.

This indicates that the signals can be separated based on the eigenvectors. When a selected eigenvector is applied as the weighting, the array antenna will form a beam on the signal and form nulls on the other signals. This weighting shall hereinafter be referred to as an “Orthogonal Eigen-Weighting” to indicate the projection of signals on the orthogonal eigenvectors.

The inventive method is described more fully below:

Estimate the Covariance Matrix

First, the covariance matrix is computed and can be expressed as follows:

$$R = ( \begin{matrix}{R}_{11} & {R}_{12} & & {R}_{1 M} \\ {R}_{21} & {R}_{22} & & {R}_{2 M} \\ … & … & & … \\ {R}_{M1} & {R}_{M2} & & {R}_{MM}\end{matrix} )$$

$${R}_{mn} = E \{ {r}_{m} ( t ) {r}_{n}^{*} ( t ) \} = \int {r}_{m} ( t ) {r}_{n}^{*} ( t ) ⅆ t ; for m = 1 : M and n = 1 : M .$$

The covariance matrix is symmetric and reflects the received phase offset between elements. The covariance matrix changes if the incoming signal changes its direction. If the directions of the incoming signals are fixed, the covariance matrix is unchanged.

Filtering of Covariance Matrix

The covariance matrix is influenced by receiver noise. If the Rₘₙ are evaluated over a short frame time, the covariance matrix can be averaged over a longer period of time to increase the signal to noise ratio. The lowpass filter should have a bandwidth small enough to yield high signal to noise ratio but wide enough to allow tracking the change of signal direction. In a stationary platform, the lowpass filter bandwidth can be narrowed to increase the estimation signal to noise ratio. In a dynamic environment, the lowpass filter bandwidth should be set wide enough to tolerate the change of the platform.

Compute the Eigenvalues and Eigenvectors

The covariance matrix R is next decomposed into the following factors:

R=WΣW′

where Σ is the eigenvalue matrix (diagonal matrix with eigenvalues), W is the eigenvector matrix (columns are eigenvectors corresponding to eigenvalues) and W′ is the transpose of the eigenvector matrix.

$$\sum = ( \begin{matrix}{λ}_{1} & 0 & & 0 \\ 0 & {λ}_{2} & & 0 \\ … & … & & … \\ 0 & 0 & & {λ}_{M}\end{matrix} )$$

$$W = ( \begin{matrix}{V}_{11} & {V}_{12} & & {V}_{1 M} \\ {V}_{21} & {V}_{22} & & {V}_{2 M} \\ … & … & & … \\ {V}_{M1} & {V}_{M2} & & {V}_{MM}\end{matrix} )$$

Sorting the Signal Using Eigen Parameters

The challenge is to identify which signal is the signal of interest and which are not. The signal can be characterized using both eigenvalues and eigenvectors:

(i) Detect the Signal via Eigenvalue:

In general, the desired signal has known amplitude (i.e., receiver sensitivity); thus the eigenvalue corresponding to that signal can be determined. In practical applications, interferers are generally strong. These characteristics can be used to separate the interferers from the signal. Because the eigenvalues indicate the strengths of the signal, the eigenvalues corresponding to the interferers may be expected to be larger than the eigenvalue corresponding to the signal. Hence, in accordance with present teachings, if the signal and interferers are widely separated in amplitude, the desired signal can be identified via the eigenvalue.

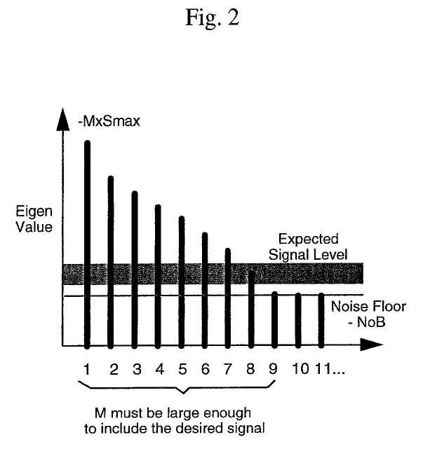

FIG. 2 is a graph showing and distribution of the eigenvalues of the received signals as may be generated by an illustrative implementation in accordance with the present teachings. The larger eigenvalues correspond to the stronger signal and the smaller corresponds to the weaker signal.

In a Direct Sequence Pseudo-Random Noise (DSPN) spread spectrum system such as the Global Positioning System (GPS) or Code Division Multiple Access (CDMA), the signal is generally below the noise level. The eigenvalue of the noise is the noise power, expressed as:

λ_{O}=E{|n(t)|²}=N_{O}B

where E indicated the expected value of, ‘λ_{O}’ is an eigen value corresponding to the noise level, ‘n(t)’ is the thermal noise, ‘N_{O}’ is one sided spectral density of the noise, and ‘B’ is the noise equivalent bandwidth. Hence, the signal of interest can be sorted out by the eigenvalue.

If the eigenvalue corresponding to the noise level (known) is used, the eigenvector can be used to put nulls to the signals stronger than the noise.

(ii) Detect the Signal Direction via its Eigenvector:

Because the eigenvectors can be used to compute the angles of arrival (AOA), the AOAs of the signals (relative to the antenna platform) can be measured. If the position of the antenna platform is known, the exact AOA can be computed. The accuracy of the AOA using the Eigen technique of present invention is sensitive to the signal strength. Therefore jammers with strong power are easily located.

(iii) Detect the Signal via Signal Characteristics

In accordance with present teachings, known characteristics about the desired signal can be used to identify the signal and its direction. If M eigen values are used to provide M signals, each signal is free from interference of other signal. Therefore, the output of the combiner 40 (FIG. 1) can be further processed to measure the frequencies and baud rates of these M signals, without interference from other signals. That is, without the inventive Eigen weighting process the desired signal would be interfered with by the jamming signals and a frequency detector or baud rate detector would be difficult to operate. The process of sorting to determine the desired signal is illustrated in Table 1 below. Having the amplitude (from eigenvalue), AOA (from eigenvector), frequency and baud rate, the system will be able to classify all M signals. The signals are sorted using a combination of the eigenvalue, eigenvector and frequency or baud rate data.

TABLE 1

| | | Signal AOA | | | | |
|---|---|---|---|---|---|---|
| Eigen | Signal | based on eigen | Signal | Center | Baud | |
| value | Power | vector | AOA | Frequency | Rate | Match |
| λ₁ | S₁ | α₁ | A₁ | f₁ | R₁ | No |
| λ₂ | S₂ | α₂ | A₂ | f₂ | R₂ | No |
| λ₃ | S₃ | α₃ | A₃ | f₃ | R₃ | Yes |
| λ₄ | S₄ | α₄ | A₄ | f₄ | R₄ | No |
| λ₅ | S₅ | α₅ | A₅ | f₅ | R₅ | No |

Application to Weighting

Once the eigenvectors corresponding to the interferers are determined, the eigenvectors will be used as the weighting. The output of the combiner 40 may be expressed as:

$${S}_{k} ( t ) = {W}_{k}^{′} ( \begin{matrix}{r}_{1} ( t ) \\ {r}_{2} ( t ) \\ … \\ {r}_{M} ( t )\end{matrix} )$$

$${S}_{k} ( t ) = \sum {W}_{kj} {r}_{j} ( t )$$

$${W}_{k} = \frac{{w}_{k}}{\vert {w}_{k} \vert} ,$$

where Wₖ is the normalized weighting to maintain noise at a constant level, and wₖ is the eigenvector corresponding to the k^{th} signal.

If all eigenvectors are applied then the signals will combine to form a beam which will be steered in a desired direction to increase the gain and the signals have low relative interference with respect to each other. That is M orthogonal signals are obtained. This property can be used for signal classification and identification purposes. Because the M signals are spatially orthogonal, the signal characteristics can be extracted such as frequency, bandwidth, baud rate, signal level. Adding these features with the AOA from the eigen vector characteristics, all M signal features are available to identify the signal.

$$S = [ {S}_{1} ( t ) {S}_{2} ( t ) … {S}_{k} ( t ) … {S}_{M} ( t ) ] = {W}^{′} ( \begin{matrix}{r}_{1} ( t ) \\ {r}_{2} ( t ) \\ … \\ {r}_{M} ( t )\end{matrix} )$$

$$W = [ {W}_{1} {W}_{2} … {W}_{k} … {W}_{M} ] = [ \frac{{w}_{1}}{\vert {w}_{1} \vert} \frac{{w}_{2}}{\vert {w}_{2} \vert} … \frac{{w}_{k}}{\vert {w}_{k} \vert} … \frac{{w}_{M}}{\vert {w}_{M} \vert} ]$$

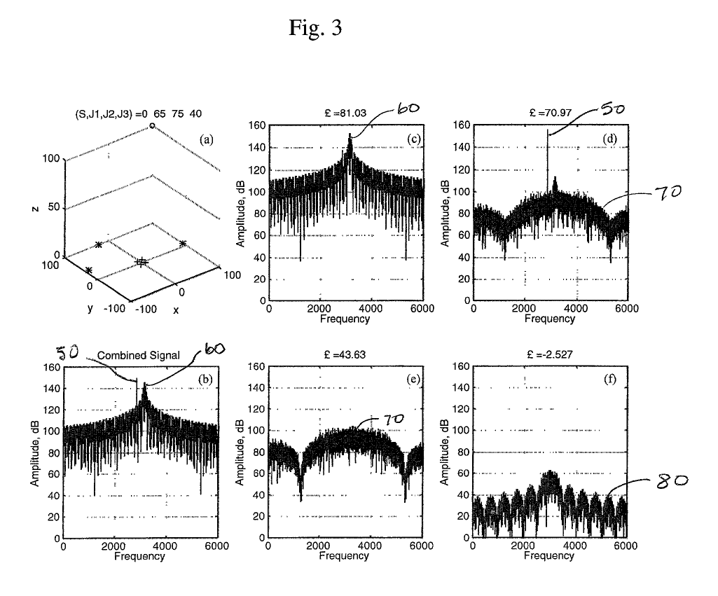

FIG. 3 is a series of diagrams illustrating the performance of an Orthogonal Eigen-Weighting estimator implement in accordance with present teachings on an adaptive array with 4 elements.

FIG. 3(a) is a schematic diagram showing the location of a 4 element antenna (+), jammers (*) and a DSPSN signal (o).

FIG. 3(b) is a diagram showing the spectrum before nulling which is a composite of three jammers and one signal. The spectrum has the following characteristics:

Jammer 1: Narrow band jammer with J/S=75 dB

Jammer 2: CW jammer with J/S=65 dB

Jammer 3: Wideband jammer with J/S=45 dB

Signal: DSPN waveform.

The four eigenvalues associated with the covariance matrix are:

λ₁=81.03 dB (strongest, corresponding to Jammer 2)

λ₂=70.97 dB (2^{nd} strongest, corresponding to Jammer 2)

λ₃=43.63 dB (3^{rd} strongest, corresponding to Jammer 3)

λ₄=−2.53 dB (4^{th} strongest, corresponding to DSPN signal)

Note that in FIG. 3(b) no weighting is applied. Accordingly, the continuous wave (CW) jamming signal 50 and narrowband jamming signal 60 are prominent.

FIG. 3(c) shows the spectrum of FIG. 3(b) resulting from a use of the eigenvector associated with eigenvalue λ₁ as the weighting. Here, is evident that the narrowband jammer 60 has gain while other signals are reduced in amplitude.

FIG. 3(d) shows the spectrum of FIG. 3(b) resulting from a use of the eigenvector associated with eigenvalue λ₂ as the weighting. Here, the CW jammer 50 has gain while other signals are reduced in amplitude. Note the presence of a wideband jamming signal 70.

FIG. 3(e) shows the spectrum of FIG. 3(b) resulting from a use of the eigenvector associated with eigenvalue λ₃ as the weighting. Here, the wideband jammer 70 has gain while the other signals are reduced in amplitude.

FIG. 3(f) shows the spectrum of FIG. 3(b) resulting from a use of the eigenvector associated with eigenvalue λ₄ as weighting. Here, the desired signal (DSPN) has gain while the jamming signals 50, 60, and 70 are almost removed. That is, the jammers are substantially suppressed leaving the DSPN waveform signal with detailed characteristics.

Hence, the advantages and the novel features of the Orthogonal Eigen-Weighting system method of the present invention are:

(1) The use of eigenvector to form a beam on the signal of interest and at the same time simultaneously form nulls on multiple interferes.

(2) The cancellation factor is squarely proportional to the interference power, thus removing strong interferers.

(3) The use of eigenvalues and eigenvectors to sort and identify the signal characteristics.

(4) The technique provides signal isolation from interference in the spatial domain to support a Multiple Access capability (i.e., Spatial Domain Multiple Access or SDMA). With M antenna elements, the inventive technique can sort out M largest signals.

(5) The technique can be used for CDMA applications where the eigenvalue is set to the noise level thus nulling strong interferers.

(6) This technique does not concern the location of the antenna array, its arrangement, nor its pointing. The technique does not require the direction of incoming signal, which may be distorted by multipath. No geometry solution needed.

(7) The technique does not require an IMU to operate in a moving platform.

(8) The technique can be adapted to allow dynamic tracking.

Thus, the present invention has been described herein with reference to a particular embodiment for a particular application. Those having ordinary skill in the art and access to the present teachings will recognize additional modifications applications and embodiments within the scope thereof.

That is, although a principal application for the present teachings is for antenna beam forming and jammer nulling, those skilled in the art will appreciate that the invention is not limited thereto. Numerous other commercial and military applications may be found about departing from the scope the present teachings. For example, the inventive process can be used to sort and extract multiple signals, free from mutual interference. All of the eigenvectors are applied as the weighting, the M combiner outputs will yield the received signal corresponding to the M strongest signals, free of interference from other signals. Therefore this technique can separate and be used to sort and identify the characteristics of the signals via the signal power, and direction of arrival and frequency characteristics, etc.

Inasmuch as each eigenvector identifies the direction of the signal source The inventive method can be used to locate a jammer or target signal location in a dense or multipath environment, e.g., battlefield environment.

Further, the inventive method can be used for Smart antennas in a cellular telephony application. In this regard, it may be expected to be especially useful for multiple CDMA signals as in a base station application. When the eigenvectors are used to provide the weighting, the signal is beam formed to the desired direction with the maximum available gain and at the same time with the interference signal being nulled. This provides spatial orthogonality, which is another space of signal orthogonality (in addition to time, frequency and code orthogonalities).

It is therefore intended by the appended claims to cover any and all such applications, modifications and embodiments within the scope of the present invention.

Accordingly,

What is claimed is:

1. An orthogonal weighting estimator for use in a beam forming system having an array of antenna elements and a receiver associated therewith, said estimator comprising:
first means for computing eigenvalues associated with signals output by said receiver and
second means for identifying a target signal with respect to a characteristic of its associated eigenvalue.

2. The invention of claim 1 wherein said characteristic is magnitude.

3. The invention of claim 1 further including third means for computing an eigenvector for at least said target signal.

4. The invention of claim 3 further including fourth means for identifying a direction of said target signal with respect to a characteristic of its associated eigenvector.

5. The invention of claim 1 wherein said estimator includes means responsive to said signals output by said receiver for computing a covariance matrix.

6. The invention of claim 1 wherein said estimator further includes means for sorting and/or searching said eigenvalues for signals matching predetermined parameters.

7. A beam forming system comprising:
an array of antenna elements adapted to receive a plurality of signals;
at least one receiver associated with each of said elements adapted to process the signals received thereby and provide a set of intermediate signals in response thereto;
an orthogonal weighting estimator coupled to the output of said receiver and comprising:
first means for computing eigenvalues associated with said intermediate signals, and
second means for identifying a target signal with respect to a characteristic of its associated eigenvalue; and
means for applying a weighting to said target signal.

8. The invention of claim 7 wherein said characteristic is magnitude.

9. The invention of claim 8 further including third means for computing an eigenvector for at least said target signal.

10. The invention of claim 9 further including fourth means for identifying a direction of said target signal with respect to a characteristic of its associated eigenvector.

11. The invention of claim 7 wherein said estimator includes means responsive to said signals output by said receiver for computing a covariance matrix.

12. The invention of claim 7 wherein said estimator further includes means for sorting and/or searching said eigenvalues for signals matching predetermined parameters.

13. A method for orthogonal weighting estimation for use in a beam forming system having an array of antenna elements and a receiver associated therewith, said method including the steps of:
computing eigenvalues associated with signals output by said receiver and identifying a target signal with respect to a characteristic of its associated eigenvalue.

14. The invention of claim 13 wherein said characteristic is magnitude.

15. The invention of claim 13 further including the step of computing an eigenvector for at least said target signal.

16. The invention of claim 15 further including the step of identifying a direction of said target signal with respect to a characteristic of its associated eigenvector.

17. A beam forming method including the steps of:
receiving a plurality of signals via an array antenna;
computing a covariance matrix R for said received signals;
decomposing the covariance matrix to provide an eigenvalue matrix and an eigenvector matrix;
identifying at least one eigenvalue from said eigenvalue matrix;
identifying an eigenvector from said eigenvector matrix corresponding to said at least one eigenvalue; and
identifying a target signal based on a characteristic of said at least one eigenvalue.

18. The invention of claim 17 further including the step of identifying said target signal based on the magnitude of said at least one eigenvalue.

19. The invention of claim 17 further including the step of detecting a direction of said target signal using said identified eigenvector.

20. The invention of claim 17 further including the step of applying a weight to said target signal.
